(19) United States
(12) Patent Application Publication
(10) Pub. No.: US 2009/0273567 A1
(43) Pub. Date: Nov. 5, 2009

(54) Computing Device Keyboard

(76) Inventors: Milton E. Milley, Edmonton (CA); John-Michael Carolan, Edmonton (CA)

Correspondence Address: DINSMORE & SHOHL LLP, 1900 CHEMED CENTER, 255 EAST FIFTH STREET, CINCINNATI, OH, 45202, US

(21) Appl. No.: 12/434,421

(22) Filed: May 1, 2009

Related U.S. Application Data
(60) Provisional application No. 61/049,959, filed on May 2, 2008.

(51) Int. Cl. G06F 3/02; H03M 11/00

(52) U.S. Cl. 345/169; 341/22

(57) ABSTRACT

Methods and devices are provided for inputting data via a thumboard utilizing a seven (7) column by five (5) row matrix hosting 30 keys. These keys can be dynamically variable using visually alternating indicia and can provide over 150 key inputs including characters, numbers, functions, symbols, navigation controls, media controls, phone keypad characters, and special characters. The switching of key values can be controlled by either a mechanical means or a touch-sensitive matrix overlaying a low-powered key emulator—such as electronic paper (Electrophoretic Display material). Mouse pointer control and special feature keys can be arrayed around the core key layout to provide full keyboard functionality. The thumboard can be detachable for wireless remote control of a paired computing device, such as a PDA pico-projection phone.

### CROSS REFERENCE TO RELATED APPLICATIONS

This application claims priority of U.S. provisional patent application Ser. No. 61/049,959, filed May 2, 2008, which is incorporated by reference herein.

### TECHNICAL FIELD

This specification pertains to the field of data entry and wireless detachable keyboards for handheld computing devices including, but not limited to, mobile communications devices.

### BACKGROUND

The introduction of handheld computing devices since 2000, such as Personal Digital Devices (PDAs), PDA phones, Smartphones, and Ultra Mobile Personal Computers (UMPCs), has resulted in increasingly tiny keyboards (or ‘thumboards’) being introduced to facilitate data entry into such devices.

Regrettably, the corresponding reduction in keyboard size (intended to improve mobility) has the inverse effect of reducing the efficacy of data entry, particularly when significant amounts of data are input, since human fingers have not undergone a similar reduction. The result is that working with such tiny thumboards becomes increasingly difficult for larger hands—posing a particular problem for adult males in North America and Europe. Since the “business professional” demographic is well represented by a significant proportion of adult males, this market is not well served by existing thumboards or the devices to which they are attached.

Additionally, most such thumboards are designed around the QWERTY-style layout of their larger cousins, the standard computer keyboard, with an prima facie mobile standard configuration of ten (10) columns by four (4) rows of keys arranged in a ‘portrait’ orientation. Examples today include Research in Motion's (RIM) Blackberry devices (i.e. 8300 and 8800 Series), HP's iPAQ devices (i.e. 6300 and 6900 Series), and HTC's smartphones (i.e. S620 and EVDO PDA Phone Series).

While the general familiarity of QWERTY-style keyboard layouts benefits most users by reducing the learning curve, since this is the style generally taught in English-speaking schools, such layouts are based on the principal of a ‘home base’ hand position designed to minimize hand movement. Thus, QWERTY layouts facilitate data entry where hand positioning is a factor, but become an impediment to data entry where thumbing is the principal means of input, i.e. using only the thumbs or ‘pecking’ at keys using one finger (as typically performed on thumboards designed for cellular phones and PDAs).

It is well documented within the keyboard industry that QWERTY keyboard layouts were actually optimized to slow down data entry. Indeed, it is the recognition of this fact that spurred development of both the Dvorak and Maltron keyboard layouts to address this deficiency. Both designs optimize key positioning by focusing on character frequency metrics (see FIGS. 1 and 2). The higher the percentage of a character's use in the language, the closer that character is placed to a hand's ‘home’ position—with a preponderance of high-use keys placed to the right of centre based on the prevalence of right-handedness in the general population.

For thumb or single digit data entry, however, ‘home-base’ hand positioning actually obstructs rapid data entry on mobile devices. Observation of even a small sample of mobile device users today reveals that ‘touch typing’ is NOT the primary input method used on today's small mobile devices. The tiny surface area available to thumboard keys actually forces users to focus their concentration, visually, on positioning their thumb(s) more accurately on the tiny keys. Thus, a QWERTY layout only aids user input insofar as it is a familiar layout that can suffice for ‘hunt-and-peck’ data entry.

It is known in the art that entering data on a keyboard with a user's thumbs is best optimized by positioning keys along the arc through which a user's thumbs pivot from the first metacarpal of the wrist. In this regard, we acknowledge the DialKey™ feature of Microsoft's UMPC (Ultra Mobile PC, see FIG. 3) software as having recognized the efficacy of a radial keyboard layout but as failing to address the inefficiency of the QWERTY layout itself.

While keyboard patterns differ, keyboards with variable indicia have begun to appear on the market. From a hardware implementation such as the Optimus Maximus™ (see FIG. 4, http://www.artlebedev.com/everything/optimus/), which uses OLED technology to change key indicia, to the use of electrophoretic technology on cell phones (currently for viewing screens, but soon for inputs—see http://www.betanews.com/article/Motorola Unveils 9 mm Entrylevel Phone with EInk Display/1164730034 and http://gizmodo.com/gadgets/design-concept/e+ink-cellphone-techno+demoed-at-ceatec-2007-306718.php), it is clear that variable indicia will be more common in the future.

In the meantime, the Resco Keyboard Pro™ emulation software (see FIG. 5, http://www.resco.net/pocketpc/keyboard/default.asp) follows the general QWERTY layout on touchscreen devices with ease-of-use features to assist in data entry. This feature is essentially directional shifting of characters based on the direction of the stroke the user makes with their stylus or finger to derive the next logical character. This allows for accented characters to be derived from a base character simply by ‘stroking’ the character in a given direction. Different characters are displayed until the stylus or finger is lifted, at which time the output is determined. The Resco also assists by enabling word completion so that users do not have to enter full text to spell a word.

Fitaly™ keyboard emulation software (see FIG. 6, www.fitaly.com) takes a different approach based on three character patterns representing 70% of the most frequently used characters in English: “ital”, “ne”, “dors”. Although this pattern is arranged around the ‘ne’ characters in a centralized columnar fashion, which supports the arc of the thumb for typing, the pattern is not linked to mnemonic patterns and actually results in non-usable key positions (i.e. blank keys) in its basic configuration. Efficiencies, however, are derived from specialized ‘sliding’ stylus functions to effectively allow alternating characters to be represented by a single key position.

A second impediment to data entry on small thumboards is the inconvenient reality that, as more keys are placed on a device, more space is required to hold them. This logically results in a larger thumboard AND mobile device (impairing its mobility characteristics) OR smaller keys (impairing its input friendliness). Traditionally, the compromise has been to remove non-essential keys, such as special characters (i.e. “(,), [,], {,}, ̂, <,>”, etc.) and special keys (i.e. HOME, END, PAGEUP, PAGEDOWN, F1-F12, etc.), and either finding an alternative means of implementing them (i.e. providing an additional software keyboard emulator with similarly tiny virtual keys) or designing mobile applications that do not require their use.

In the past, this has not been a significant impediment because expectations were low for mobile computing applications. But as advances in pico-projection systems from 3M, Microvision, Texas Instruments, Displaytech and others overcome the limitations of the small screens in mobile devices (by allowing for larger, projected interfaces and more robust applications), the need for greater input control over mobile devices will increase exponentially. This is because complex graphical interfaces are already making significant inroads into personal information managers, PDA phones, and mobile video devices. This is evidenced by Palm's, Research in Motion's, and Microsoft's GUI interfaces on a variety of mobile devices including Treo® Phones, Blackberrys®, and Windows Mobile® devices. Having the ability to project the user interface onto nearby surfaces will certainly increase consumer demand for even more ‘desktop’ applications running on handheld devices.

This anticipated demand for ‘desktop’ interfaces from handheld devices further implies that greater than 104-key keyboard functionality will ultimately be required from diminutive keyboards that fit in the palm of your hand.

It should be noted here that voice recognition technologies will NOT solve the input problem for small, mobile devices so long as environments exist where sound pollution/obstruction is a problem (factory floors, space/vacuums, underwater, etc.) or where people suffer severe speech impediments.

Therefore, there is a need in the art for methods and designs that improve data entry via thumb or single-digit thumboard inputs for mobile devices needing to deliver even greater desktop functionalities on the move.

### SUMMARY

A tiny keyboard or thumboard design is provided that can offer over 150-key combinations on mobile devices based on simple mnemonics to aid in the learning of new key positions. In replacing the QWERTY layout for mobile devices, key proximities have been optimized based on character frequencies of the English language so as to reduce the distance the thumb (or any single-digit) travels in composing common English words. But by positioning keys around character frequencies AND mnemonic patterns, layouts are easy to learn and the ease of entering text by thumb is improved.

Further, in order to minimize the width of mobile devices utilizing the design or, alternatively, to increase key sizes without affecting device width, the design similarly reduces the number of physical, or emulated, keys to a matrix of less than 10 columns—typically, around a core of seven character columns. The resulting matrix of 30 keys then relies on the dynamic switching of key outputs, via electronic or mechanical means, to reflect ‘logical’ keys rather than fixed keys in order to repurpose key positions.

Lastly, the defined switching mechanism is designed to simplify the switching of key outputs so as to not impose arduous ‘extra’ inputs during data entry.

### BRIEF DESCRIPTION OF FIGURES

FIG. 1 is a diagram depicting a prior art Dvorak simplified keyboard layout.

FIG. 2 is a diagram depicting a prior art mapping of English character frequencies to an embodiment of the invention based on Maltron™ statistics.

FIG. 3 is a diagram depicting a prior art Microsoft Dialkey™ QWERTY keyboard layout.

FIG. 4 is a diagram depicting a prior art Optimus Maximus™ keyboard layout comparison to the present invention.

FIG. 5 is a diagram depicting a prior art Resco Keyboard Pro™ keyboard layout comparison to the present invention.

FIG. 6 is a diagram depicting a prior art Fitaly™ keyboard layout comparison to the present invention.

FIG. 7 is a schematic diagram depicting one embodiment of a keyboard having dynamically assignable keys showing a 30-key layout inclusive of the 26-character lowercase standard English alphabet.

FIG. 8 is a diagram depicting a breakout of the 6 key mnemonics used to learn the thumboard key layouts.

FIG. 9 is a schematic diagram depicting the keyboard of FIG. 7 showing a 30-key layout inclusive of the 26-character UPPER case English alphabet and repurposing of the two punctuation keys.

FIG. 10 is a schematic diagram depicting the keyboard of FIG. 1 showing a 30-key layout inclusive of the 26-character UPPER case English alphabet in CAP-lock mode with further repurposing of the two punctuation keys.

FIG. 11 is a schematic diagram depicting the keyboard of FIG. 7 showing a repurposing of the 30-key layout for Punctuation, Symbol and special character key entry.

FIG. 12 is a schematic diagram depicting the keyboard of FIG. 7 showing a repurposing of the 30-key layout for numeric entry.

FIG. 13 is a schematic diagram depicting the keyboard of FIG. 7 showing a repurposing of the 30-key layout for Function key and Navigation/Cursor Control entry.

FIG. 14 is a schematic diagram depicting the keyboard of FIG. 7 showing a repurposing of the 30-key layout for Phone key entry.

FIG. 15 is a schematic diagram depicting the keyboard of FIG. 7 showing a repurposing of the 30-key layout for Remote Media Control.

FIG. 16 is a diagram depicting a wireless keyboard for a computing device for remotely controlling a pico-projection phone.

FIG. 17A is a diagram depicting use of the keyboard of FIG. 7 to type frequently used words in the English language primarily using the upper quadrants of the thumboard.

FIG. 17B is a diagram depicting use of the keyboard of FIG. 7 to type additional frequently used words in the English language primarily using the upper quadrants of the thumboard.

FIG. 18 is a block diagram depicting one embodiment of the keyboard of FIG. 7.

FIG. 19 is a block diagram depicting an alternate embodiment of the keyboard of FIG. 7.

FIG. 20 is a flowchart depicting one embodiment of the method of operation of the keyboard of FIG. 7.

### DETAILED DESCRIPTION

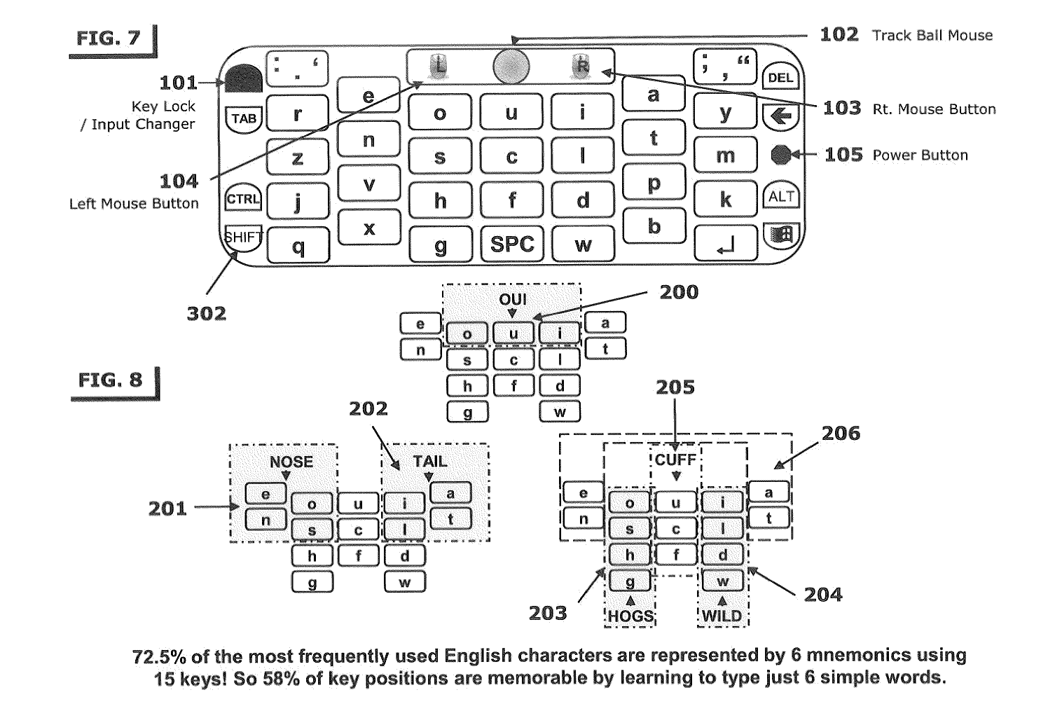

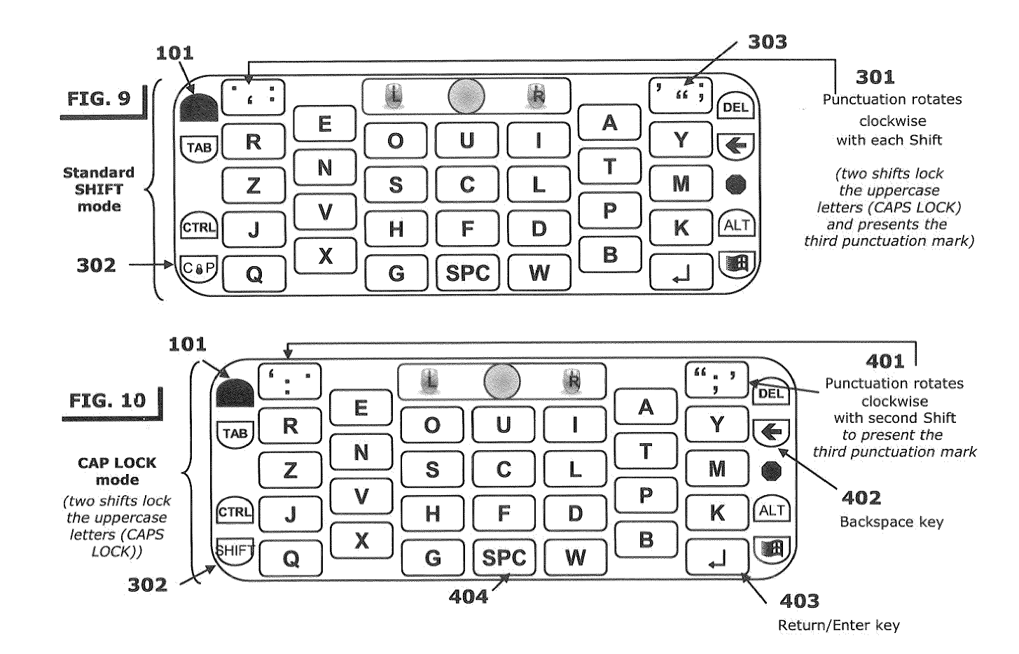

In one embodiment, a basic key layout (see FIG. 7) for a thumboard is provided that can consist of a primary matrix of 30 keys fanned out, to both left and right, from the centre of a seven column array. In one embodiment, these keys can occupy five rows. These 30 keys can contain the 26-character English alphabet, two prime punctuation keys (301 of FIG. 9 and 401 of FIG. 10), one Spacebar key, and one Return/Enter key (403). All of these keys can be repurposed or dynamically assigned to display other keys depending on the view required, i.e. for numbers, navigation/cursor control, function keys, additional punctuation, symbols and other special characters. In other embodiments, the thumboard can comprise a matrix of “m” columns and “n” rows having a plurality of dynamically variable or assignable keys where the values for “m” and “n” can be selected as to what is suitable for any particular computing device or application.

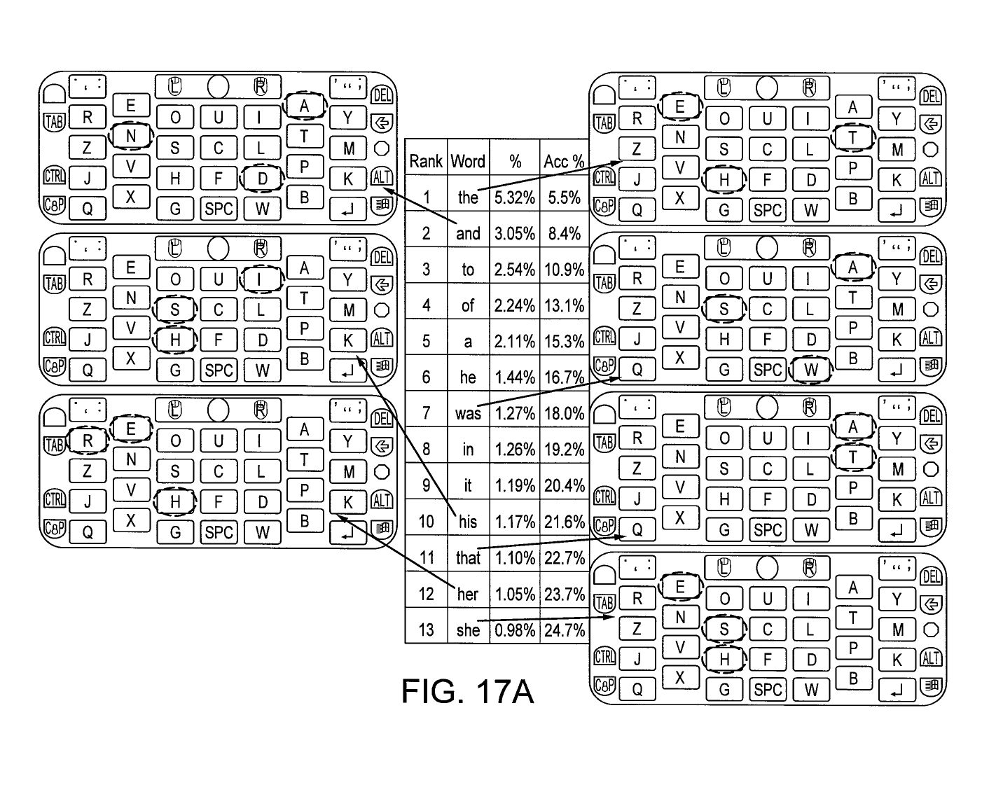

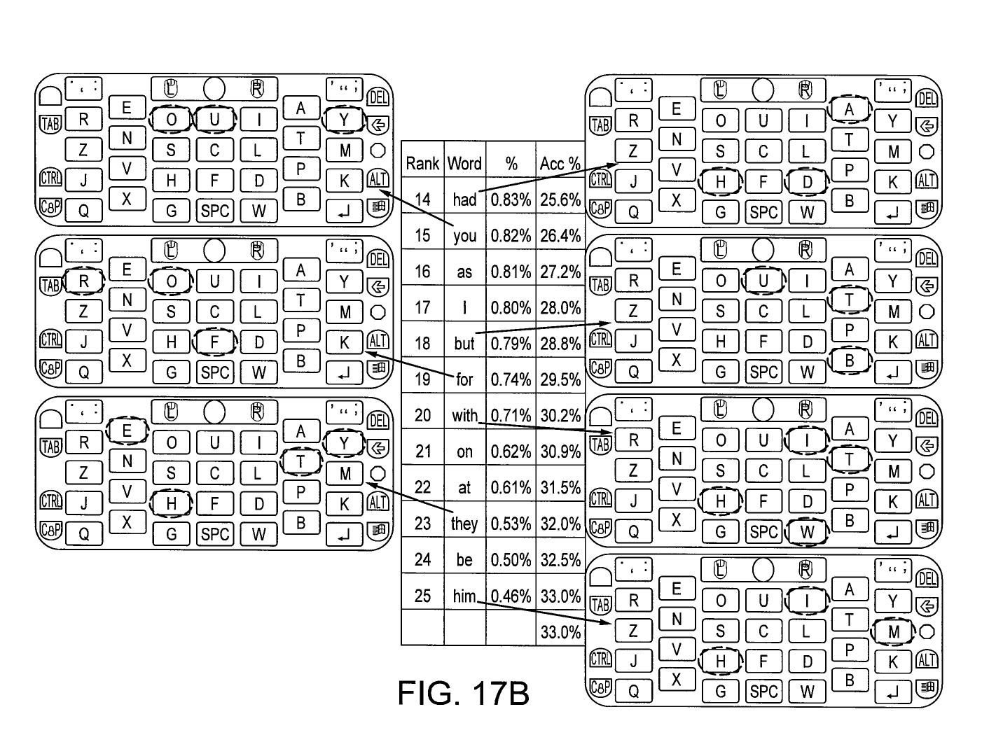

Keys can be arranged in opposing arcs from the centre to be traversed by left and/or right thumbs to minimize the width of a mobile and/or wireless computing input device while providing greater than 104-key data input. As such, rows can be ‘fanned’ from the bottom left and right points of the keyboard so as to sweep keys up to the outsides from a central point. This sweep allows the thumbs to traverse the arc in a more natural fashion, i.e. rotating from the first metacarpal of the wrist, than if keys are arrayed in straight rows. However, by not making the curve too extreme, it is possible for one thumb, centred at the base of the keypad, to sweep the majority of keys without strain and with only a slight stretch needed for topmost outer keys. (FIGS. 17A and 17B show the highlighted key positions needed to type the 25 most common words in the English language using one embodiment. As shown, these keys may be easily reached using one thumb centrally positioned or two placed to both left and right of centre.)

The primary feature enabling the dynamic transformation of keys is, in one embodiment, a button or scroll wheel that can serve as an Input Changer 101 (see FIG. 7) for altering underlying visually perceptible indicia and their associated outputs. This key emulation can be by electronic or mechanical means but, in a representative embodiment, can be a ‘flashed’ particulate electrophoric (electronic paper) display, such as available from e-Ink Corporation and SiPix Imaging, Inc., but with subsecond response times. Because of its low power requirement, and its ability to retain an image after power is turned off, electronic paper allows for underlying key identifiers, i.e. the letters, characters, numbers and symbols, to be displayed beneath a touch-sensitive matrix even when power is not being consumed. This means that the underlying screen does not have to be refreshed except when key images need to change below the active matrix. However, given the demands of data intensive applications, the interface must refresh or change in less than a second so as not to impede data entry.

While the top surface may be flat in one embodiment, the touch-sensitive matrix can be covered by a clear panel of raised key ‘pillows’, i.e. filled bubbles of transparent, flexible laminated mylar/polyethelyne, or similar material, denoting fixed key positions in other embodiments. Such raised ‘keys’ can provide a tactile feedback to the user while still allowing for dynamic repurposing of key indicia below the touch-sensitive matrix. Pressure on the bubble, from being touched by thumbs, digits, or other means, can focus the ‘touch’ on the touch screen below to signal that a key is ‘pressed’.

To reduce the number of keys required for the thumboard, any key can be repurposed by changing the underlying image, as well as the logical output, below the ‘key’ position. Thus, even Input Changer button 101 itself can be programmatically or mechanically transformed into a Key Lock button merely by determining its intended function by how the button is used. In one embodiment, the Input Changer can be changed to the Key Lock by holding the button for longer than a pre-determined period of time, such as two seconds. This would then programmatically lock out all inputs on all other keys until the Key Lock button was pressed again to restore Input Changer 101 and unlock the other keys.

In other embodiments, the thumboard can host intelligence to alternate keyboard outputs to match the visual indicia displayed at any time. This may be programmatically determined using system-on-chip functionality or may be determined using Java applets or some similar lightweight programming language/service stored in Flash memory (or similar media). Such media can be removable or be embedded in the thumboard device. Because of the variable indicia, Power button 105 can be provided to control the power usage of the touch screen and power the software enabling the dynamic switching of indicia and transmission of outputs. However, it is similarly envisioned that such alternating visual indicia and key outputs can be mechanically derived.

In one embodiment of the key layout, the number of vertical key columns can be seven—excluding special purpose keys to be described later. All 26 letters of the English alphabet can be arranged below a top, centred row of standard vowels, “a, e, i, o, u” (FIG. 7). Referring to FIG. 8, the arrangement of these vowels can be re-ordered (left to right) to “e, o, u, i, a” such that the three-letter French word “OUI” forms the center point for the key patterns that follow. This French word for ‘YES’ is familiar to most English speakers and can be used to establish simple mnemonic 200 upon which to build further mnemonic patterns.

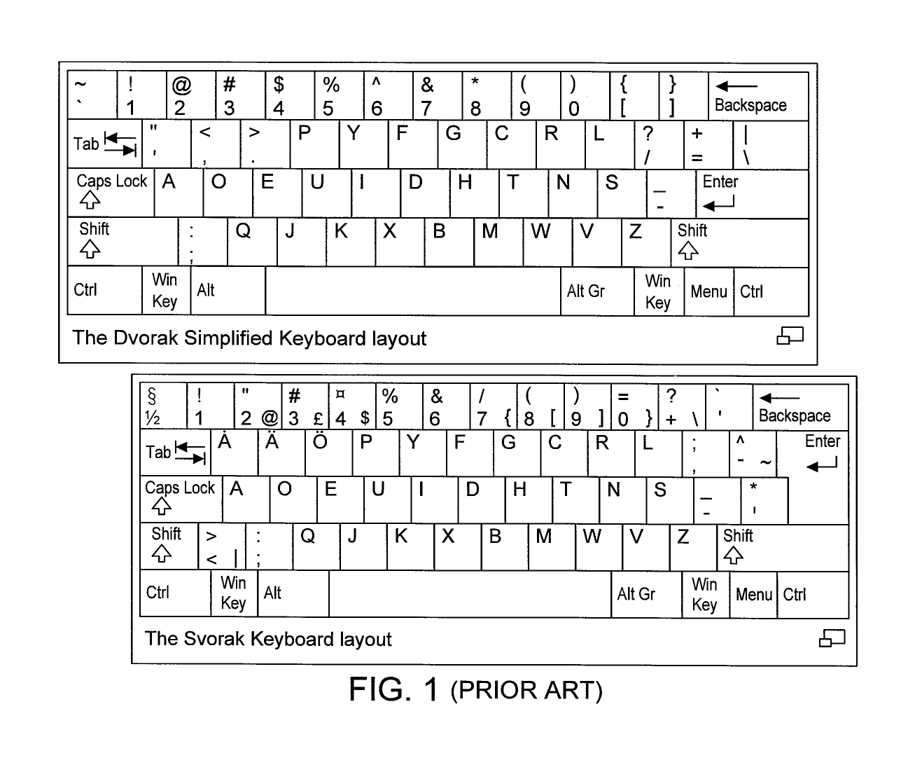

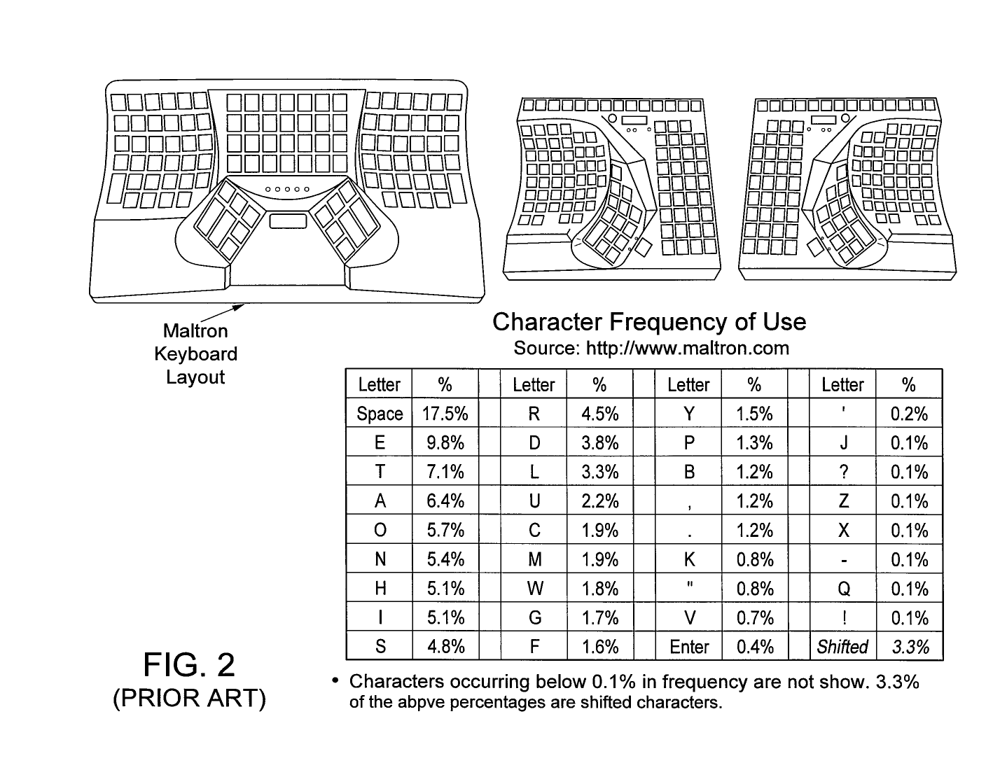

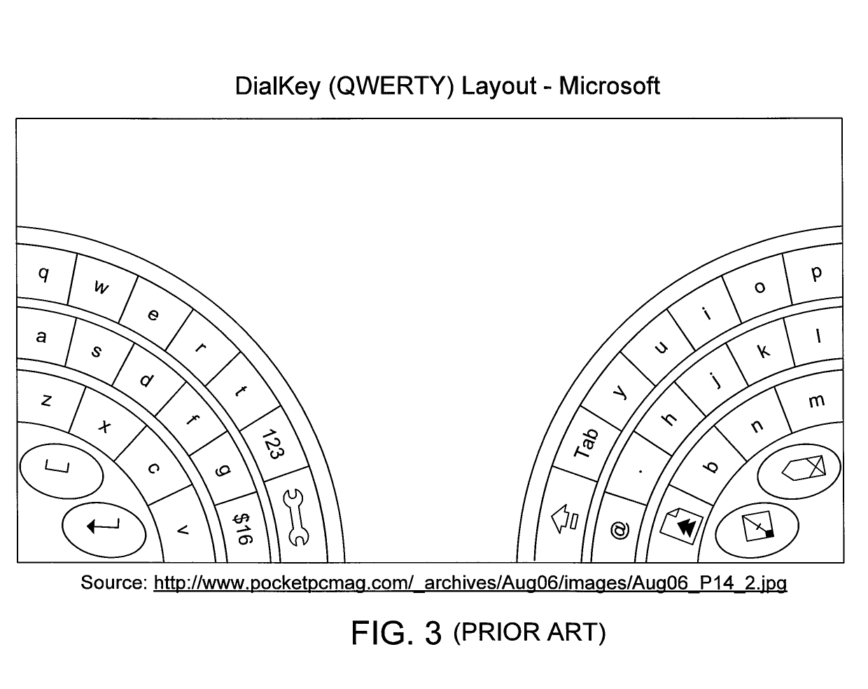

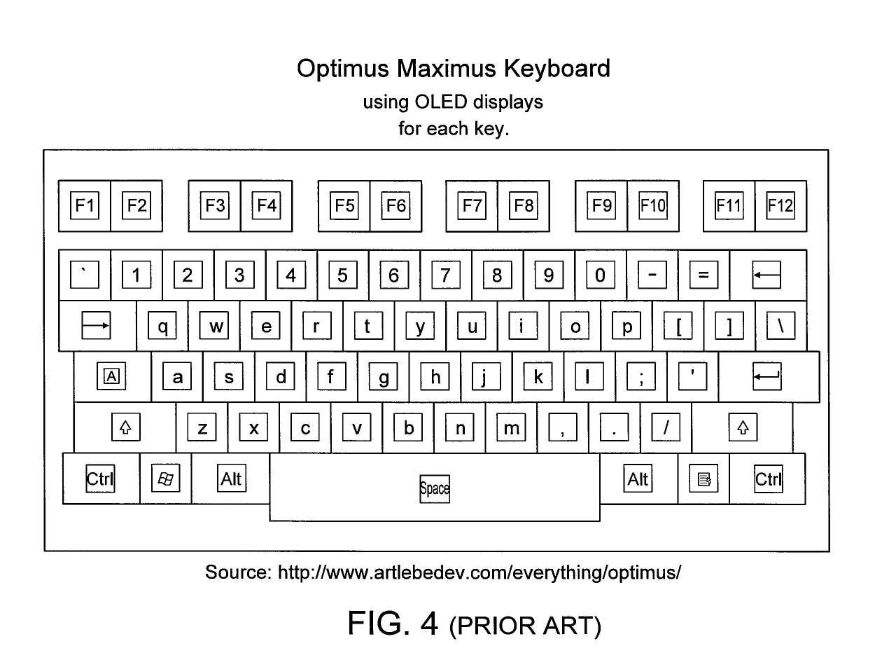

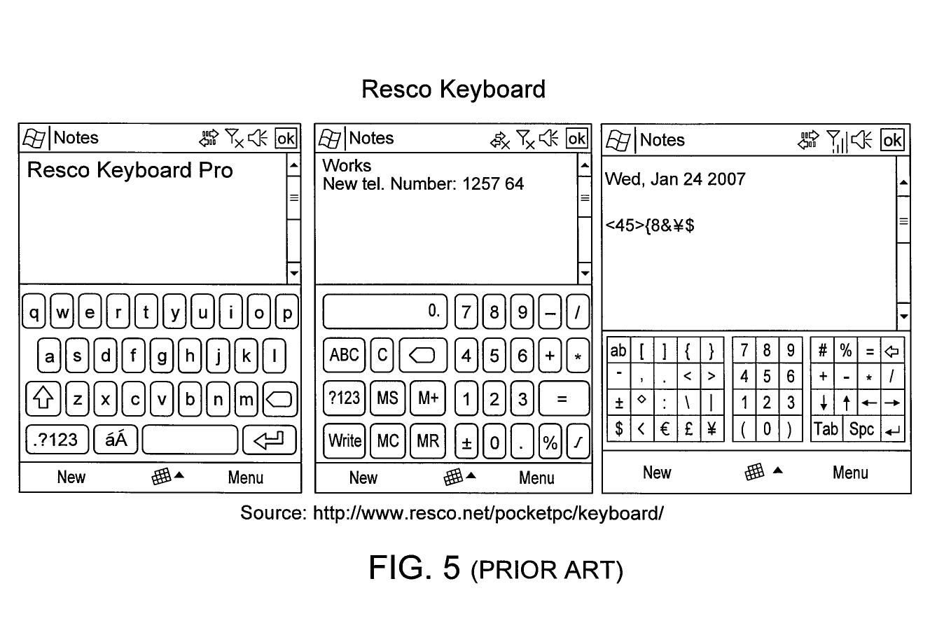

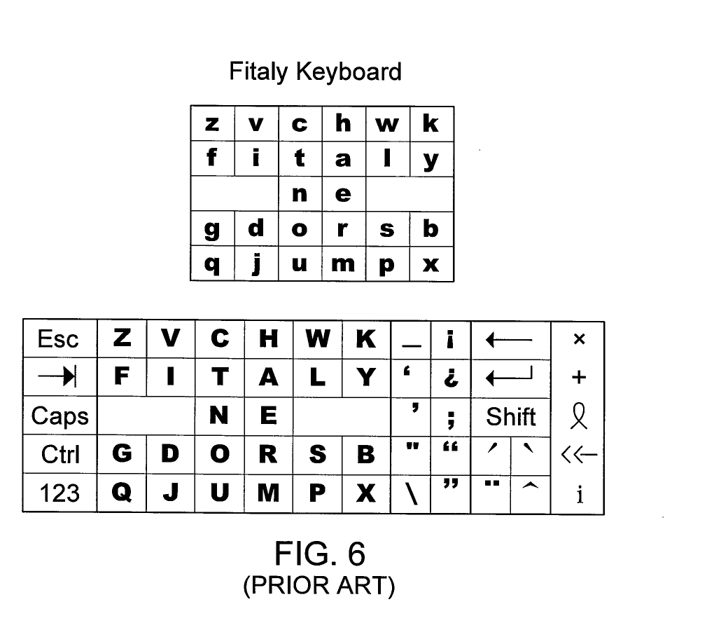

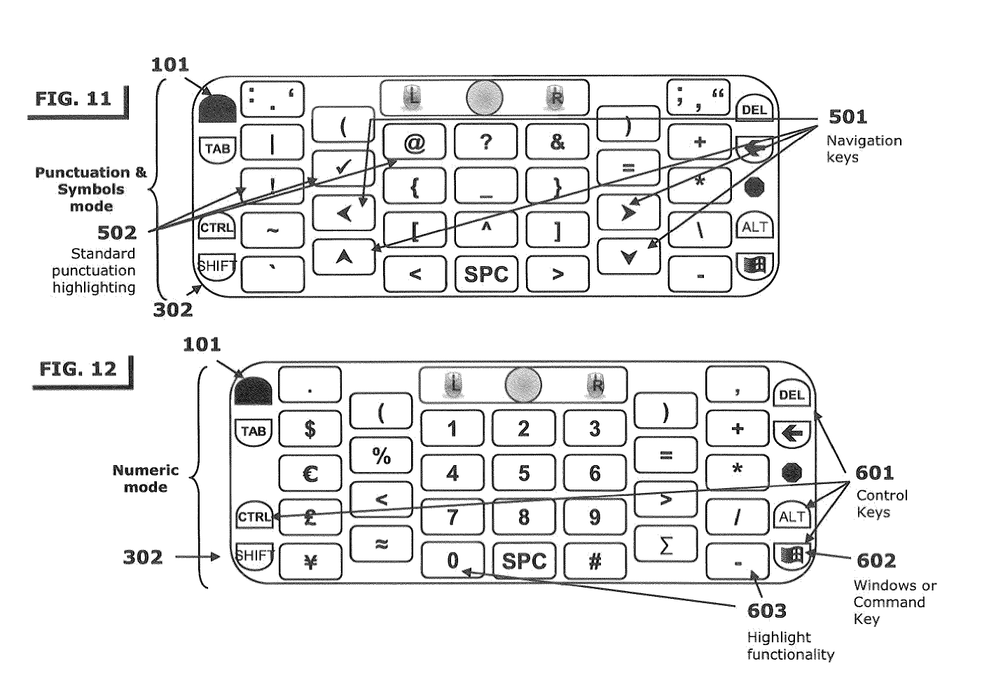

In one embodiment, the keyboard can use shading, colouring, and/or highlighting (502 in FIG. 11 and 603 in FIG. 12) of special key patterns, such as for the vowels shown in FIG. 1, to signal the changing modes represented by the visual indicia. This draws user attention to these patterns to augment the learning of key positions—as well as to visually represent changes to thumboard modes represented by FIGS. 7, 9, 10, 11, 12, 13, 14 and 15 (lowercase alphabet, uppercase alphabet, CAP lock alphabet, punctuation/symbols, numeric, function key, phone, and media controller respectively). The highlighting patterns recommended are shown in the Figures noted.

Anchoring the vowel mnemonic described above is the further placement of the letters “N” and “S” below the “E” and “O”, left of centre, to form second mnemonic 201, “Nose” as shown in FIG. 8. At the opposite end of the vowel pattern the letters “L” and “T” are placed below the “I” and “A” to form the antonymous mnemonic 202, “Tail”. As shown in FIG. 7, the order of the characters does not have to be exact, i.e. does not have to be in the specific order of T-A-I-L, to be understood. This is due to the human mind's ability to distinguish words in spite of letter randomization. (See Rawlinson, Graham E. (1976), The significance of letter position in word recognition. Unpublished PhD Thesis, Psychology Department, University of Nottingham, Nottingham UK.)

With just four characters linked in proximity to the above five-vowel pattern, 35% of the placement of the English alphabet is now easily memorized by learning these simple patterns. See Table 1 below for the character frequency chart supporting this statistic.¹ ¹http://www.askoxford.com/asktheexperts/faq/aboutwords/frequency?view=uk. The third column represents proportions, taking the least common letter (q) as equal to 1. The letter E is over 56 times more common than Q in forming individual English words.

TABLE 1

| | | | | | |
|---|---|---|---|---|---|
| E | 11.1607% | 56.88 | M | 3.0129% | 15.36 |
| A | 8.4966% | 43.31 | H | 3.0034% | 15.31 |
| R | 7.5809% | 38.64 | G | 2.4705% | 12.59 |
| I | 7.5448% | 38.45 | B | 2.0720% | 10.56 |
| O | 7.1635% | 36.51 | F | 1.8121% | 9.24 |
| T | 6.9509% | 35.43 | Y | 1.7779% | 9.06 |
| N | 6.6544% | 33.92 | W | 1.2899% | 6.57 |
| S | 5.7351% | 29.23 | K | 1.1016% | 5.61 |
| L | 5.4893% | 27.98 | V | 1.0074% | 5.13 |
| C | 4.5388% | 23.13 | X | 0.2902% | 1.48 |
| U | 3.6308% | 18.51 | Z | 0.2722% | 1.39 |
| D | 3.3844% | 17.25 | J | 0.1965% | 1.00 |
| P | 3.1671% | 16.14 | Q | 0.1962% | (1) |

Further mnemonics can now be added to further reinforce the learning of key placements. In the illustrated embodiment of FIG. 8, the letters “H” and “G” are arranged vertically below the “O” and “S” to create the randomized mnemonic 203, “Hogs”. The letters “D” and “W” are vertically aligned with the “I” and “L” above to form another randomized mnemonic 204, “Wild”. By placing the letters “C” and “F” directly below the “U” in the centre column we now form the mnemonic 205, “Cuff”, and so on. FIG. 8 shows the recommended base mnemonics. (The flanking pairs ‘e-n’ and ‘a-t’ can also form an enclosing mnemonic 206, which is “Neat”.)

As noted earlier, because of the arc traversed by left and/or right thumbs, the rows of the keyboard can be ‘fanned’ from the bottom right and left points of the keyboard so as to position keys slightly higher to the outsides than to the middle. This sweep allows the thumbs to traverse the arc in a more natural fashion than if the keys were arrayed in straight rows. By not making the curve too extreme, it is possible for one thumb, centred at the base of the keypad, to sweep the majority of keys without strain and with only a slight stretch required to reach the topmost outer keys.

Thus, in the illustrated embodiment, the top ‘row’, irregular by virtue of the described arcs, can contain the following seven keys, from left to right: ‘r-e-o-u-i-a-y’. (The Track Ball and ‘mouse’ buttons—102, 103, and 104 of FIG. 7—plus the two prime punctuation keys—301 of FIG. 9 and 401 of FIG. 10—are not considered part of the top ‘row’ but can serve as peripheral inputs.)

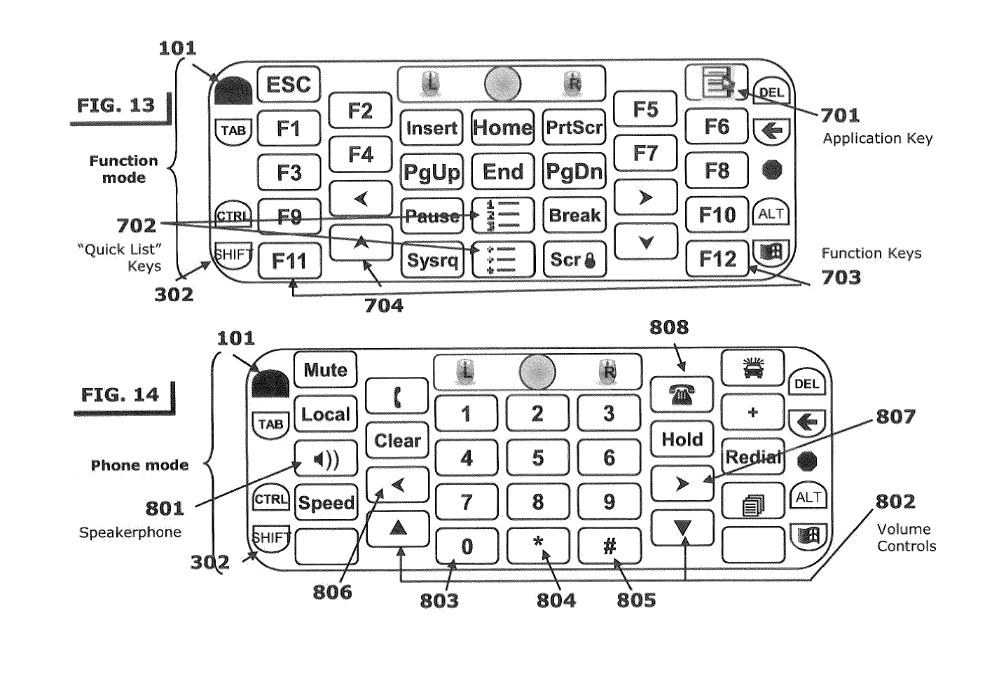

The second ‘row’, can contain the keys ‘z-n-s-c-l-t-m’. The third, ‘j-v-h-f-d-p-k’. The fourth row, ‘q-x-g-SPACE-w-b-RETURN’. Although the SPACE bar can be made larger than the surrounding keys, this is optional since 1) mobile handheld PC users typically look at keys as they type, 2) shading of the indicia below the space bar ‘key’ can be different from that of other keys (and therefore can make the Space Bar appear more prominent), 3) its placement at the centre bottom intersection of the two arcs makes it easily accessible by both thumbs, and 4) repurposing of this key for Function, Phone, and Media Controller modes makes varying the key size less desirable (FIGS. 13 through 15).

Combined with the character frequency considerations stated above, the one embodiment of the keyboard can distribute all remaining consonants to facilitate a relatively even distribution of characters from left to right of centre. This is to maintain roughly equal distributions of the most frequently used characters to both left and right of the centre column, inclusive of the centre column. This can allow approximately equal usage by both left- and right-handed users without having to modify key placements to support one demographic or the other.

In one embodiment, the reduction of the number of key columns has the added benefit of enabling a reduction in keyboard width relative to current standards, or, alternatively, enabling wider keys without increasing the width of the device. Depending on the placement of special keys, it is in fact possible to reduce device width, or increase key sizes, by between 10 to 30 percent over key sizes currently in use—based on the current 10-column QWERTY standard for mobile computing devices.

Were the 26 English character keys sufficient for all data entry, then the above layout would suffice. However, users desire, and are demanding, full computing power in their hands and as device manufacturers build mobile devices providing more robust ‘desktop’ functionality, users will require 104+ key inputs to work with such devices. Numbers, function (F1-F12) and navigation (Home, End, PgUp, PgDn, and arrow/cursor control) keys, special purpose keys, pointer controls and more can be accommodated in the embodiment herein described.

By pressing the Shift button 302 of FIG. 9 one time, users can change the state of the default indicia from lowercase alphabet to uppercase. The alphabetic characters, and the punctuation shown in the two punctuation keys 301, now display the characters shown in FIG. 9. In the present embodiment, the left punctuation key can “rotate” the indicia clockwise from period “.” to single quotation mark “′” with one press of Shift key 302. The right punctuation key 303 can similarly rotate from comma “,” to double quotation mark “″”. Pressing any key can transmit the output associated with the displayed indicia and restore the thumboard to regular, lowercase alphabetic mode.

While in Shift mode, Shift button 302 indicia can change to show the CAP Lock button 302. Pressing the CAP Lock button 302, i.e. pressing the Shift button 302 a second time, the thumboard indicia can change to display the CAP Lock version of uppercase (FIG. 10). In this mode, the left punctuation indicia can again rotate to display the third punctuation symbol, the colon “:”. The right punctuation indicia can similarly display its third punctuation symbol, the semi-colon “;”. All characters can remain as uppercase until Shift key 302 is pressed again. In CAP Lock mode, Shift key 302's indicia can be restored to display ‘Shift’ indicating that pressing it can unlock the CAP Lock when pressed.

At any time, pressing Input Changer button 101 previously described can switch the displayed keys to alternate input modes: alphabetic, punctuation/symbol, function, phone, media controller and numeric. Simultaneously pressing Shift key 302 while pressing Input Changer 101 can reverse this order and cycle modes backwards. If the user is at the start or end of a mode sequence, the next press of Input Changer 101 can advance to the beginning mode (alphabetic) or to the next sequential mode. For this reason, the Numeric mode is placed in the last position so that users can move with one input from Alphabetic to Numeric mode by using Input Changer button 101 in conjunction with Shift key 302.

In one embodiment, the order of presentation of Input Changer 101 can be:

1. alphabetic (default mode is lowercase)

2. punctuation/symbol

3. function

4. phone (optional),

5. media controller (optional), and

6. numeric

Each press of Input Changer button 101 can sequentially advance the indicia to display the next mode. (In an alternate embodiment, a scroll wheel can also be substituted for Input Changer button 101.) To access Punctuation/Symbol mode from Alphabetic mode, the user can merely press Input Changer button 101 once (without Shift key 302). (Since not all mobile devices will require the phone or media controller modes, these modes are deemed optional and may not be implemented in other embodiments of this.)

Although not shown in the Figures presented, any of the non-alphabetic modes can similarly utilize Shifting characters, symbols, or functions as desired by the manufacturer. In such embodiments, within a specific mode, pressing Shift key 302 can rotate the indicia as described previously with respect to the Punctuation key (FIGS. 7, 9 and 10), but with additional keys supporting such functionality as well.

For ease of use, when in Punctuation/Symbol (FIG. 11) or Function (FIG. 13) mode, pressing any key except Control, Command, or Navigation/Cursor Control keys (501) can transmit the output and restore the indicia to alphabetic or numeric mode awaiting the user's next input. If the user entered a numeric digit or symbol before navigating to the Punctuation/Symbol or Function mode, then it can be the numeric mode that is restored. Otherwise, it can be the alphabetic mode. The navigation described here is the “Home, End, PgUp, PgDn” and Right, Left, Up and Down cursor controls 704. They can be excluded from the auto-restore to last mode rule since users may wish to navigate fairly extensively before resuming inputs. However, where symbol or function inputs are pressed instead, text or numeric inputs can generally follow.

When alphabetic mode is restored from another mode, the default lowercase alphabetic mode can again be made active unless the mode was in CAP Lock. For example, if the user were in Shift mode when they navigated to Punctuation mode, pressing the Shift and Input Changer buttons, or entering a symbol, can restore the lowercase alphabetic characters. But if the user navigated from the CAP Locked alphabetic mode, his or her return to alphabetic mode can place them again in CAP Locked alphabetic mode.

In the Punctuation/Symbol mode (FIG. 11), all characters, numbers or symbols previously displayed when Input Changer button 101 was pressed can be replaced with the standard punctuation and symbols shown. Shading, colouration and/or highlighting is used to focus the user's attention on key, high-use punctuation and symbols such as “!, ✓, @, ?, &, =, *”. “Flanking” patterns of braces, brackets, and cursor control keys can be similarly positioned around the centre column core to establish an easy to remember pattern—like bookends. So “<” and “>” oppose each other—as do “{” and “}”.

In one embodiment, the Punctuation Keys (from standard alphabet mode) can remain in the same position in Punctuation/Symbol mode. However, as illustrated, highlighting, shading and/or colouration shift can draw the user's attention to the current mode that the device is in. Such shifting highlight patterns are another mnemonic that can be used to teach users how to learn the thumboard—providing a visual that instantly warns users if they are in the wrong mode for their desired use. Pressing Shift key 302 can rotate the punctuation in the Punctuation Keys in the same manner as described for alphabetic mode.

In other embodiments, patterns can be established across modes that complement each other such that learning one pattern enables transference of this knowledge to other modes. So the plus (+), minus (−) and multiply (*) signs in FIG. 11 hold the same positions in Numeric Mode (FIG. 12). However, the intent here is NOT to recognize them as numeric symbols in Punctuation/Symbol mode. Hence, the divide (/) symbol in FIG. 14 can be replaced with a backslash (\) in FIG. 11. So too, in this mode, the ‘numeric’ symbols actually represent ‘the same as’ (=), ‘also’ (+), ‘hyphen’ (-) and ‘asterisk’ (*); whereas, in Numeric mode they represent their arithmetic function. (So ‘percent’ (%), although a common symbol, is recognized as only having a numeric association and is not included in Punctuation/Symbol mode but appears only in Numeric mode.)

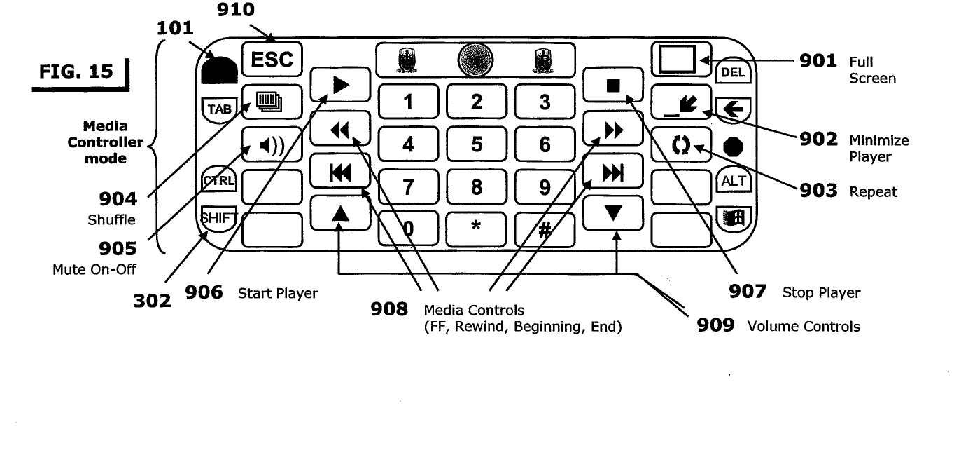

In Numeric mode (FIG. 12), the number pad can be centred and mirror the number pads used in Phone (FIG. 14) and Media Controller (FIG. 15) modes. In other embodiments, shading, colouring and/or highlighting of the numbers can be implemented to draw the attention of the user to aid in numeric entry. Standard arithmetic symbols can be placed, in the illustrated embodiment, on the rightmost column, as shown. Currency symbols can be arrayed on the opposite leftmost column. Again, patterns of placements can be derived that logically aid the user in discovering the patterns for ease of use. It should be noted here that the standard Punctuation Keys from the alphabetic mode can be represented in Numeric mode as single punctuation indicia since the omitted punctuation is not used for numeric entries. (Where such characters are required by a manufacturer, the punctuation/symbol mode can be activated. But other embodiments may retain the omitted punctuation where degrees, minutes and other longitudinal/latitudinal markup characters are desired.)

This pattern also holds true for the cursor control keys that repeat for each of the punctuation/symbol, function, and (partial) phone modes (FIGS. 11, 13, and 14). It is also echoed abstractly by the volume buttons in FIGS. 8 and 9 as well as by the media controls in FIG. 15 based on the directional ‘appearance’ of the controls. Wherever possible, the intent is to retain visual patterns to augment the learning of key placements.

In Function mode, the function keys 703 F1 through F12 (FIG. 13) can flank the navigation keys 704 (including Home, End, PgUp, PgDn) as shown—again, mirroring the flanking patterns used for brackets and braces in Punctuation/Symbol mode. The function keys can be shaded, coloured and/or highlighted to draw attention to these specific keys. However, other special purpose keys can also be included in this mode: “Insert, PrtScr (Print Screen), Pause, Break, Scroll Lock, and SysRq (System Request).

In this mode, the punctuation keys can be dynamically replaced with indicia to provide the ESC character and Application Key 701. Two new keys 702 are shown that represent Quick List keys for numbering and bulleting in word processing programs. Although not currently supported by existing software programs, it is envisioned that the outputs of these two keys can result in toggling on and off the Number and Bullet list features of these programs. This may be by triggering a macro function or may be customized inputs developed by the software manufacturer in conjunction with the thumboard manufacturer to support this functionality.

In the optional Phone mode (FIG. 14), the numeric pad can be centralized, but the numbers can increase from left to right and from up to down—instead of the standard layout on most computer keyboards. This follows the standard phone key layout with one exception. The zero (0) button 803 can be placed to the left of the asterisk (*) button 804 and the pound (#) button 805 to remain consistent with the Numeric and Media Controller mode layouts as shown in FIGS. 12 and 15, respectively. Again, the purpose is to simplify the learning curve for new users.

The current implementation suggests possible layouts for standard phone functions such as Answer/Dial key 809, Disconnect/Hang Up key 808, Mute key 808, Speakerphone key 801, Volume Controls 802 and left/right cursor navigation arrow keys 806 and 807, but other than the numeric pad layout, these placements are less rigidly imposed and any suitable arrangement of these keys can be used.

Regardless of the mode that the user is in at the time of an incoming call, the device can be configured that it can automatically navigate to the Phone mode (assuming cellular functionality is provided) to await the user's decision to answer or ignore the call. (In one embodiment, the Disconnect/Hang Up key 808 can serve as the Ignore button, but there are two unused keys at the bottom of the key layout that could be assigned to this function depending on the manufacturer's needs.)

In the optional Media Controller mode (FIG. 15), the indicia can be repurposed to display standard media controls such as Start key 906, Stop key 907, Media Controls 908 (Fast Forward, Rewind, Beginning and End), Mute key 905 and Volume Up/Down Controls 909. In anticipation that the thumboard may be used in a manner consistent with standard keyboards, ESC key 910 can also be provided to restore media players to their standard formats from Full Screen 901 view (or may be used whenever ESC key 910 is required to terminate an ongoing application function). The current media player can also be minimized using Minimize Player button 902. The looping of music or videos can be enabled by pressing the Repeat Key 903. In one embodiment, this same key can toggle on and off the repeat track functionality. In other embodiments, Shuffle key 904 can also toggle in this fashion to randomly select music tracks, if appropriate.

As shown in FIGS. 7 and 9 through 15, the illustrated embodiments of the thumboard can also feature trackball and left/right mouse button functionality above the top row of keys (FIG. 7: 102, 103, and 104) to accommodate the pointer movement required to navigate around robust graphical interfaces. Thus, the thumboard can serve as both keyboard and mouse for any mobile device to which it attaches or to which it may communicate (if wirelessly connected).

Special purpose keys, including Backspace key 402, Tab key 106, Control keys 601 (see FIG. 12) (which include CTRL key 108, ALT key 109, DEL key 107, SHIFT key 302), and Windows/Command key 602 keys can be embodied in the thumboard as either ‘flanking’ column keys (placed to the right and left) or as additional rows of keys above or below the 30-keys described herein. FIGS. 9 through 15 show one embodiment of the flanking arrangement so described. If arranged above or below the alphanumeric keys, the arrangement can allow for as much as a 30% reduction in width from existing 10 column keyboards on mobile devices.

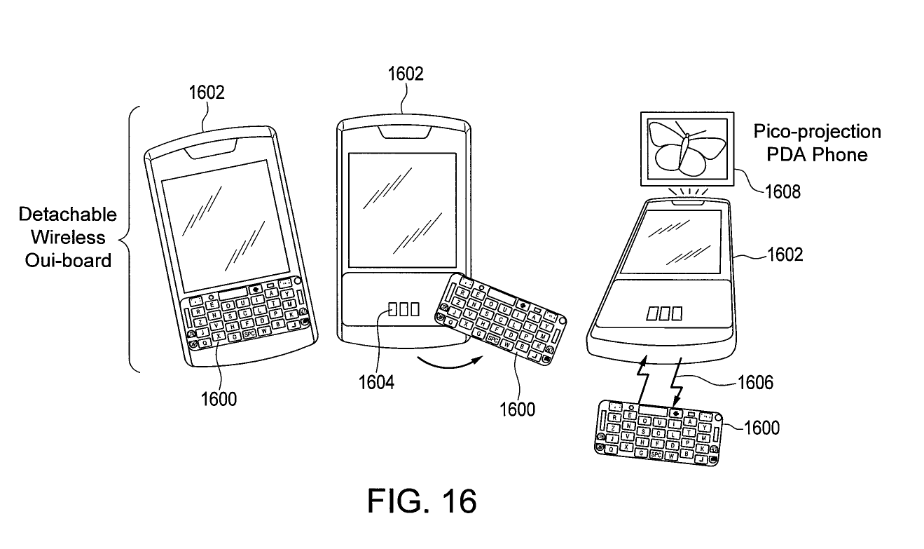

In other embodiments, the thumboard can be removed from a mobile device while retaining a wireless connection to it (see FIG. 16). In this way, users can carry one device, which is separable into two parts for easier use. Thus, a mobile pico-projection phone can be wirelessly controlled without the user being forced to work directly from the projection unit. This embodiment envisions a detachable wireless version of the thumboard, using Bluetooth or a similar wireless protocol, being paired with the mobile device.

When attached to the mobile device, the thumboard can input directly into the device. When detached, inputs to the thumboard can be transmitted wirelessly to the mobile device with which it is paired and provide the same level of control as though still attached. Mouse pointer control can be implemented by similar means, whether wirelessly or while connected to the mobile device, via track ball 102 attached to the thumboard as shown in FIGS. 7 through 15.

### Examples

The keyboard described herein can be implemented as, but is not limited to, an attached input device in a computing device such as, but not limited to, a mobile phone, PDA, or Ultra Mobile PC for input directly into the device. As such, it can serve as a full keyboard and mouse for data entry. Referring to FIG. 16, keyboard 1600 is first shown attached to handheld computing device 1602 and then detached from device 1602. When keyboard 1600 is attached to device 1602, power can be supplied to and data can be transferred between keyboard 1600 and device 1602 through electrical contacts 1604. When keyboard 1600 is detached from device 1602, keyboard 1600 can communicate with device 1602 via wireless communication link 1606, which can comprise the Bluetooth® protocol, IEEE 802.11 protocol, infrared communications protocol or any suitable wireless communications protocol. In other embodiments, device 1602 can comprise projection means to display image 1608 on a wall or screen or other suitable image display surface.

Similarly, the keyboard described herein can be implemented as, but is not limited to, a detachable, wireless input device for a computing device such as, but not limited to, similar mobile computing or entertainment devices. In this fashion, it can be separable from the main device while maintaining wireless control over the main device.

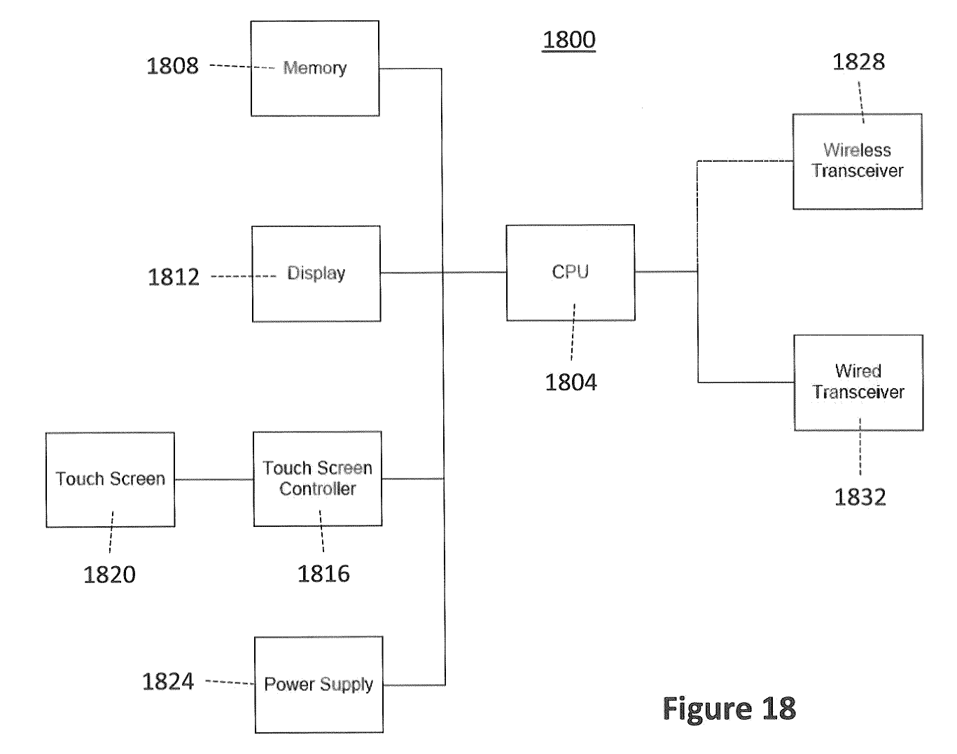

Referring to FIG. 18, block diagram 1800 is shown, which represents one embodiment of the keyboard described herein. In this embodiment, the keyboard can comprise central processing unit (“CPU”) 1804, which is operatively coupled to memory 1808, display 1812, touch screen controller 1816 and power supply 1824. In embodiments of the keyboard comprising a touch screen displaying soft keys, touch screen controller 1816 can be further operatively coupled to touch screen 1820 for controlling the display of soft keys on display 1812 and detecting when a soft key is depressed. In this embodiment, CPU 1804 can be operatively coupled to one of wired transceiver 1832 and wireless transceiver 1828 or both. Wired transceiver 1832 enables the keyboard to communicate with a handheld computing device when the keyboard is installed on the device. Wireless transceiver 1828 enables the keyboard to communicate with the device the keyboard is detached from the device using any one or a plurality of wireless communications protocols such as Bluetooth®, IEEE 802.11 (also known as “Wi-Fi”), infrared wireless protocols or any other suitable wireless communications protocol.

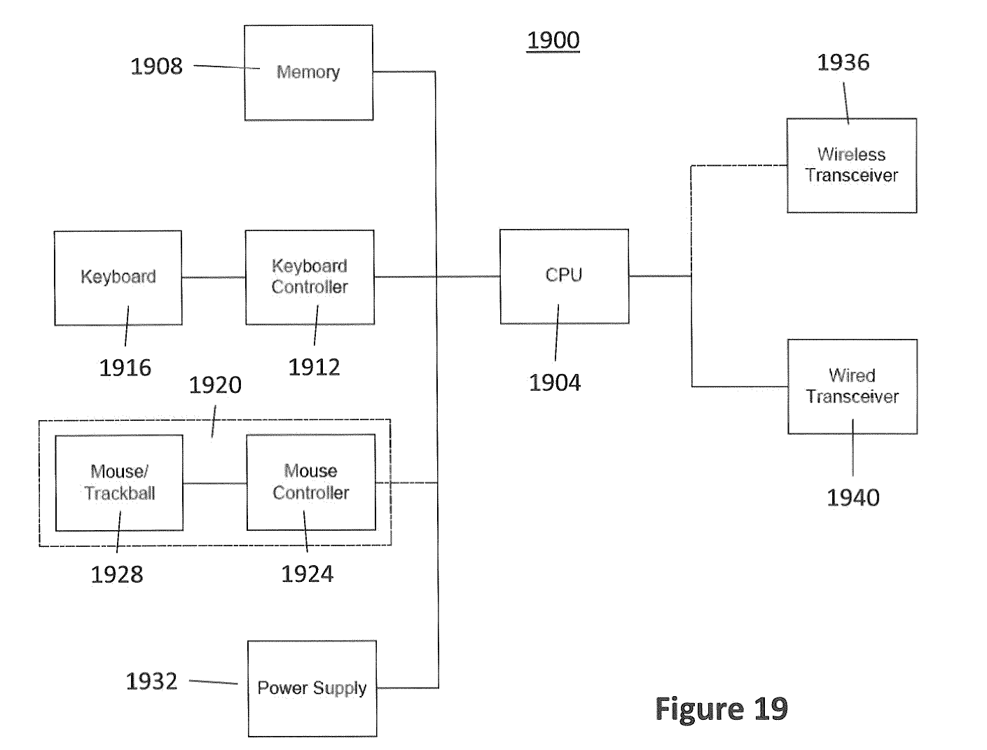

Referring to FIG. 19, block diagram 1900 is shown, which represents another embodiment of the keyboard described herein. In this embodiment, the keyboard can comprise central processing unit (“CPU”) 1904, which is operatively coupled to memory 1908, keyboard controller 1912 operatively coupled to keyboard 1916, mouse controller 1924 operatively coupled to mouse/trackball 1928 and power supply 1932. In embodiments of the keyboard comprising tactile keys that can be configured to display a user-defined symbol therein, keyboard controller 1912 can control the symbols associated with any key on keyboard 1916 and for detecting when any such key is depressed. In such embodiments, the keyboard can comprise a mouse or trackball to emulate mouse functions on the keyboard. In these embodiments, mouse controller 1924 can monitor any movement of mouse/trackball 1928 and generate an appropriate signal associated of such movements for transmittal to the handheld computing device via CPU 1904 and wired transceiver 1340 and wireless transceiver 1936 or both. Wired transceiver 1940 enables the keyboard to communicate with a handheld computing device when the keyboard is installed on the device. Wireless transceiver 1936 enables the keyboard to communicate with the device the keyboard is detached from the device as discussed above.

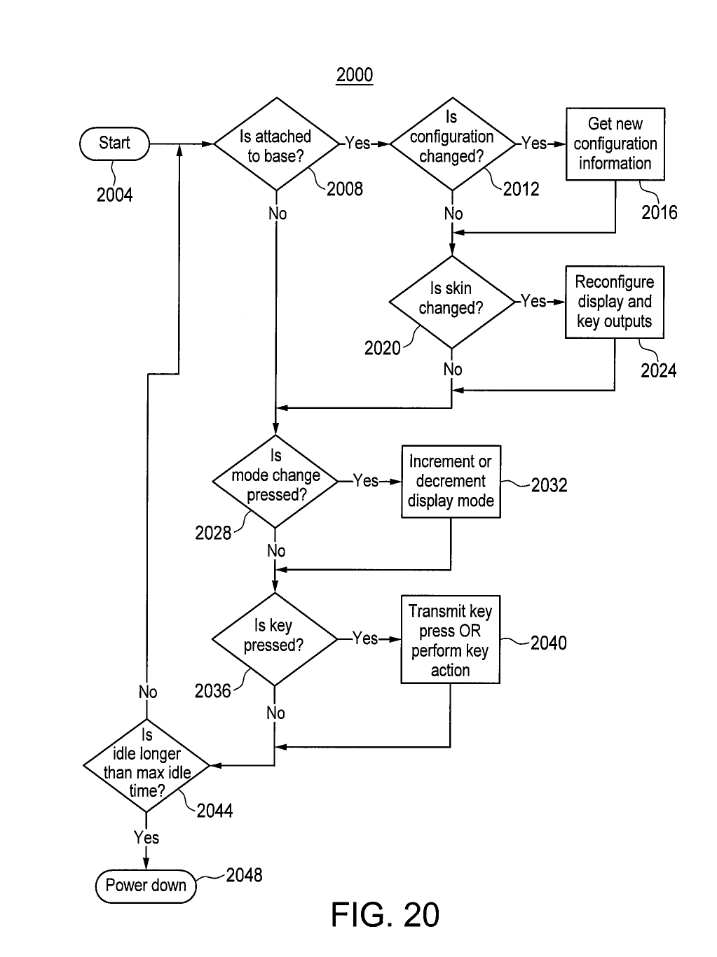

Referring to FIG. 20, flowchart 2000 is shown, which represents the method or steps taken by operating software disposed or embedded in one embodiment of the keyboard described herein. The steps of flowchart 2000 can include: from Start 2004, the method determines if the keyboard is attached to a handheld computing device at step 2008. If “no”, the method progresses to step 2028. If “yes”, the method determines if the keyboard's configuration has changed at step 2012. If “no”, the method proceeds to step 2020. If “yes”, the new configuration information is obtained and the method proceeds to step 2020. At step 2020, the method determines if the keyboard's image configuration or “skin” has changed. If “no”, the method proceeds to step 2028. If “yes”, the keyboard display is reconfigured and the method proceeds to step 2028.

At step 2028, the method determines if the keyboard's mode has been pressed. If “no”, the method proceeds to step 2036. If “yes”, the keyboard's mode is changed upwards or downwards incrementally at step 2032 depending on the mode button being pressed, and the method then proceeds to step 2036. At step 2036, the keyboard determines if any key has been depressed. If “no”, the method proceeds to step 2044. If “yes”, the method determines at step 2040 what key was depressed and/or to perform the function associated with the depressed key, and the method proceeds to step 2044. For the purposes of this specification and the claims contained herein, the term “depressed” is defined to include the pressing of a tactile button having image display means and the touching of a soft key displayed on a touch screen.

At step 2044, the method determines if the keyboard has been idle longer than the maximum idle time. If “no”, the method returns to step 2008 to repeat the whole method. If “yes”, the method then proceeds to step 2048 to power the keyboard down.

Although a few embodiments have been shown and described, it will be appreciated that various changes and modifications might be made without departing from the scope of the invention. The terms and expressions used in the preceding specification have been used herein as terms of description and not of limitation, and there is no intention in the use of such terms and expressions of excluding equivalents of the features shown and described or portions thereof, it being recognized that the scope of the invention is defined and limited only by the claims that follow.

We claim:

1. A keyboard for a handheld computing device, comprising:
a) a plurality of dynamically variable or assignable keys arranged into a matrix of “m” rows and “n” columns operatively disposed in a keyboard housing, the housing operatively disposed on the computing device;
b) means for assigning a predetermined value, character or function for each of the plurality of keys for at least one mode of functionality, whereby each key comprises a predetermined value, character or function for each mode of functionality;
c) display means for displaying the value, character or function assigned to each key; and
d) transmitting means for transmitting at least one signal to the computing device whenever at least one of the plurality of keys is depressed, the at least one signal corresponding to the value, character or function assigned to the depressed key.

2. The keyboard as set forth in claim 1, wherein the matrix comprises at least 4 rows of keys.

3. The keyboard as set forth in claim 2, wherein the matrix comprises at least 7 columns of keys.

4. The keyboard as set forth in claim 2, wherein the at least 4 rows of keys comprises:
a) a first row of keys comprising the values, characters or functions: r, e, o, u, i, a and y;
b) a second row of keys comprising the values, characters or functions: z, n, s, c, l, t and m;
c) a third row of keys comprising the values, characters or functions: j, v, h, f, d, p and k; and
d) a fourth row of keys comprising the values, characters or functions: q, x, g, Space Bar, w, b and Return/Enter.

5. The keyboard as set forth in claim 3, wherein at least two of the columns of keys are raised in position relative to the other columns thereby creating two arcs in each of the rows of the keys whereby all of the keys can be depressed by a user using only their thumbs with minimal discomfort.

6. The keyboard as set forth in claim 1, further comprising means for changing or shifting the mode of functionality of the keys whereby at least one key can be assigned a new predetermined value or function.

7. The keyboard as set forth in claim 6, wherein the means for changing or shifting the mode of functionality comprise one or more selected from the group consisting of keys, toggle switches and scroll wheels.

8. The keyboard as set forth in claim 1, further comprising at least one control key consisting of one or more of the group consisting of “Delete Key”, “Backspace Key”, “ALT Key”, “CTRL Key”, “TAB Key”, “Shift Key” and “Windows® Command Key”.

9. The keyboard as set forth in claim 1, further comprising at least one dynamically variable or assignable punctuation key for typing at least one punctuation mark.

10. The keyboard as set forth in claim 1, further comprising mouse means for entering data into the computing device or navigating data displayed on the computing device.

11. The keyboard as set forth in claim 10, wherein the mouse means further comprises one or more of the group consisting of a left mouse button, a right mouse button, a joystick and a trackball.

12. The keyboard as set forth in claim 1, wherein the keyboard comprises a plurality of modes of functionality.

13. The keyboard as set forth in claim 12, wherein the keyboard can operate in one or more modes of functionality selected from the group consisting of lower case text entry mode, shifted upper case text entry mode, Caps Lock upper case text entry mode, punctuation/symbols text entry mode, numeric mode, function mode, phone mode and media controller mode.

14. The keyboard as set forth in claim 1, where in at least a first mode of functionality, the matrix further comprises:
a) a first row of keys comprising the values, characters or functions: r, e, o, u, i, a and y;
b) a second row of keys comprising the values, characters or functions: z, n, s, c, l, t and m;
c) a third row of keys comprising the values, characters or functions: j, v, h, f, d, p and k; and
d) a fourth row of keys comprising the values, characters or functions: q, x, g, Space Bar, w, b and Return/Enter.

15. The keyboard as set forth in claim 14, further comprising at least one punctuation key.

16. The keyboard as set forth in claim 1, where in at least a second mode of functionality, the matrix further comprises:
a) a first row of keys comprising the values, characters or functions: “|”, “(”, “@”, “?”, “&”, “)” and “+”;
b) a second row of keys comprising the values, characters or functions: “!”, “✓”, “{”, “_”, “}”, “=” and “*”;
c) a third row of keys comprising the values, characters or functions: “˜”, “Left Arrow symbol: [symbol] “[”, “̂”, “]”, “Right Arrow symbol: [symbol] and “\”; and
d) a fourth row of keys comprising the values, characters or functions: “′”, “Up Arrow symbol: [symbol] “<”, Space Bar, “>”, “Down Arrow symbol: [symbol] and “−”.

17. The keyboard as set forth in claim 16, further comprising at least one punctuation key.

18. The keyboard as set forth in claim 1, where in at least a third mode of functionality, the matrix further comprises:
a) a first row of keys comprising the values, characters or functions: “$”, “(”, 1, 2, 3, “)” and “+”;
b) a second row of keys comprising the values, characters or functions: “ [symbol] ”, “%”, 4, 5, 6, “=” and “*”.
c) a third row of keys comprising the values, characters or functions: “£”, “<”, 7, 8, 9, “>” and “/”; and
d) a fourth row of keys comprising the values, characters or functions: “¥”, “≈”, 0, Space Bar, “#”, “Σ” and “−”.

19. The keyboard as set forth in claim 18, further comprising at least one punctuation key.

20. The keyboard as set forth in claim 1, where in at least a fourth mode of functionality, the matrix further comprises:
a) a first row of keys comprising the values, characters or functions: F1, F2, Insert, Home, PrtScr, F5 and F6;
b) a second row of keys comprising the values, characters or functions: F3, F4, PgUp, End, PgDn, F7 and F8;
c) a third row of keys comprising the values, characters or functions: F9, “Left Arrow symbol: [symbol] Pause, “Quick List Key—Numeric”, Break, “Right Arrow symbol: [symbol] and F10; and
d) a fourth row of keys comprising the values, characters or functions: F11, “Up Arrow symbol: [symbol] SysRq, “Quick List Key—Bulleted”, “Scroll Lock symbol: Scr [symbol] “Down Arrow symbol: [symbol] and F12.

21. The keyboard as set forth in claim 20, further comprising one or more keys selected from the group consisting of Escape (“ESC”) key and Context Menu key.

22. The keyboard as set forth in claim 1, where in at least a fifth mode of functionality, the matrix further comprises:
a) a first row of keys comprising the values, characters or functions: Local Area Code prefix, “Talk symbol: [symbol] 1, 2, 3, “Hang Up symbol: [symbol] and “+”;
b) a second row of keys comprising the values, characters or functions: “Speak/Mute symbol: [symbol] Clear, 4, 5, 6, Hold and Redial;
c) a third row of keys comprising the values, characters or functions: Speed, “Left Arrow symbol: [symbol] 7, 8, 9, “Right Arrow symbol: [symbol] and “Phone Directory symbol: [symbol] and
d) a fourth row of keys comprising the values, characters or functions: “blank key reserved for future use”, “Volume Up symbol: ▴”, 0, “*”, “#”, “Volume Down symbol: ▾” and “blank key reserved for future use”.

23. The keyboard as set forth in claim 22, further comprising one or more keys selected from the group consisting of Mute key and Emergency Number key.

24. The keyboard as set forth in claim 1, where in at least a sixth mode of functionality, the matrix further comprises:
a) a first row of keys comprising the values, characters or functions: “Media Shuffle symbol”, “Play/Pause symbol: [symbol] 1, 2, 3, “Stop symbol: ▪” and “Toggle Minimize/Maximize symbol: [symbol]
b) a second row of keys comprising the values, characters or functions: “Speaker/Mute symbol: [symbol] “Reverse symbol: [symbol] 4, 5, 6, “Fast Forward symbol: [symbol] and “Repeat symbol: [symbol] ”;
c) a third row of keys comprising the values, characters or functions: “blank key reserved for future use”, “Go To Beginning symbol: [symbol] 7, 8, 9, “Go To End symbol: [symbol] and “blank key reserved for future use”; and
d) a fourth row of keys comprising the values, characters or functions: “blank key reserved for future use”, “Volume Up symbol: ▴”, 0, “*”, “#”, “Volume Down symbol: ▾” and “blank key reserved for future use”.

25. The keyboard as set forth in claim 24, further comprising one or more keys selected from the group consisting of Escape key (“ESC”) and Full Screen Key.

26. The keyboard as set forth in claim 1, wherein the plurality of keys are selected from one or more of the group consisting of images representing soft keys displayed on a touch screen and tactile keys having means for displaying the value or function assigned thereto.

27. The keyboard as set forth in claim 26, wherein the display means comprises the touch screen whereby the value or function assigned to a soft key is displayed within the image of the soft key on the touch screen.

28. The keyboard as set forth in claim 1, wherein the plurality of keys are disposed in a keyboard housing, the housing operatively disposed on the computing device.

29. The keyboard as set forth in claim 28, wherein the keyboard housing further comprises means for detaching the keyboard housing from the computing device.

30. The keyboard as set forth in claim 29, wherein the transmitting means further comprises:
a) wireless communication means for transmitting the at least one signal to the computing device; and
b) power means for powering the keyboard when the keyboard is detached from the computing device.

31. The keyboard as set forth in claim 30, wherein the wireless communications means is configured to transmit the at least one signal to the computing device in accordance with one or more wireless communications transmission protocols selected from the group consisting of Bluetooth® and IEEE 802.11.

32. A keyboard for a handheld computing device having at least one mode of functionality, where in a first mode of functionality, the keyboard comprises:
a) a first row of keys comprising the values, characters or functions: r, e, o, u, i, a and y;
b) a second row of keys comprising the values, characters or functions: z, n, s, c, l, t and m;
c) a third row of keys comprising the values, characters or functions: j, v, h, f, d, p and k; and
d) a fourth row of keys comprising the values, characters or functions: q, x, g, Space Bar, w, b and Return/Enter.

33. The keyboard as set forth in claim 32, where in a second mode of functionality, the keyboard comprises:
a) the first row of keys comprising the values, characters or functions: “|”, “(”, “@”, “?”, “&”, “)” and “+”;
b) the second row of keys comprising the values, characters or functions: “!”, “✓”, “{”, “_”, “}”, “=” and “*”;
c) the third row of keys comprising the values, characters or functions: “˜”, [symbol] “[”, “̂”, “]”, [symbol] and “\”; and
d) the fourth row of keys comprising the values, characters or functions: “′”, [symbol] “<”, Space Bar, “>”, [symbol] and “−”.

34. The keyboard as set forth in claim 33, where in a third mode of functionality, the keyboard comprises:
a) the first row of keys comprising the values, characters or functions: “$”, “(”, 1, 2, 3, “)” and “+”;
b) the second row of keys comprising the values, characters or functions: [symbol] “%”, 4, 5, 6, “=” and “*”.
c) the third row of keys comprising the values, characters or functions: “£”, “<”, 7, 8, 9, “>” and “/”; and
d) the fourth row of keys comprising the values, characters or functions: “¥”, “≈”, 0, Space Bar, “#”, “Σ” and “−”.

35. The keyboard as set forth in claim 34, where in a fourth mode of functionality, the keyboard comprises:
a) the first row of keys comprising the values, characters or functions: F1, F2, Insert, Home, PrtScr, F5 and F6;
b) the second row of keys comprising the values, characters or functions: F3, F4, PgUp, End, PgDn, F7 and F8;
c) the third row of keys comprising the values, characters or functions: F9, “Left Arrow symbol: [symbol] Pause, “Quick List—numeric”, Break, “Right Arrow symbol: [symbol] and F10; and
d) the fourth row of keys comprising the values, characters or functions: F11, “Up Arrow symbol: [symbol] SysRq, “Quick List—bulleted”, “Scroll Lock symbol: Scr [symbol] “Down Arrow symbol: [symbol] and F12.

36. The keyboard as set forth in claim 35, where in a fifth mode of functionality, the keyboard comprises:
a) the first row of keys comprising the values, characters or functions: Local Area Code prefix, “Talk symbol: [symbol] ”, 1, 2, 3, “Hang Up symbol: [symbol] and “+”;
b) the second row of keys comprising the values, characters or functions: “Speak/Mute symbol: [symbol] Clear, 4, 5, 6, Hold and Redial;
c) the third row of keys comprising the values, characters or functions: Speed, “Left Arrow symbol: [symbol] 7, 8, 9, “Right Arrow symbol: [symbol] and “Phone Directory symbol: [symbol] and
d) the fourth row of keys comprising the values, characters or functions: “blank key reserved for future use”, “Volume Up symbol: ▴”, 0, “*”, “#”, “Volume Down symbol: ▾” and “blank key reserved for future use”.

37. The keyboard as set forth in claim 36, where in a sixth mode of functionality, the keyboard comprises:
a) the first row of keys comprising the values, characters or functions: “Media Shuffle Key”, “Play/Pause symbol: [symbol] 1, 2, 3, “Stop symbol: ▪” and “Toggle Minimize/Maximize symbol: [symbol]
b) the second row of keys comprising the values, characters or functions: “Speaker/Mute symbol: [symbol] “Reverse symbol: [symbol] 4, 5, 6, “Fast Forward symbol: [symbol] and “Repeat symbol: [symbol] ”;
c) the third row of keys comprising the values, characters or functions: “blank key reserved for future use”, “Go To Beginning symbol: [symbol] 7, 8, 9, “Go To End symbol: [symbol] and “blank key reserved for future use”; and
d) the fourth row of keys comprising the values, characters or functions: “blank key reserved for future use”, “Volume Up symbol: “▴”, 0, “*”, “#”, “Volume Down symbol: ▾” and “blank key reserved for future use”.
